(19) United States
(12) Patent Application Publication
(10) Pub. No.: US 2024/0347508 A1
(43) Pub. Date: Oct. 17, 2024

(54) SEMICONDUCTOR PACKAGE AND METHOD OF MANUFACTURING THE SEMICONDUCTOR PACKAGE

(71) Applicant: Samsung Electronics Co., Ltd., Suwon-si (KR)

(72) Inventor: Jihyun Lim, Suwon-si (KR)

(21) Appl. No.: 18/584,007

(22) Filed: Feb. 22, 2024

(30) Foreign Application Priority Data
Apr. 13, 2023 (KR) 10-2023-0048667

(51) Int. Cl. H01L 25/065; H01L 23/00; H01L 23/04; H01L 23/31; H01L 23/538; H01L 25/10

(52) U.S. Cl. CPC H01L 25/0655; H01L 23/041; H01L 23/3107; H01L 23/5383; H01L 24/16; H01L 24/32; H01L 24/73; H01L 24/48; H01L 25/0657; H01L 25/105; H01L 2224/16227; H01L 2224/32145; H01L 2224/32225; H01L 2224/48227; H01L 2224/73204; H01L 2224/73265; H01L 2225/06568

(57) ABSTRACT

A semiconductor package includes a lower redistribution wiring layer having lower redistribution wirings; an encapsulation structure on the lower redistribution wiring layer; a plurality of conductive bumps between the lower redistribution wiring layer and the encapsulation structure; and an adhesive layer attaching the lower redistribution wiring layer and the encapsulation structure. The encapsulation structure includes a core substrate having a cavity formed therein, at least one semiconductor chip in the cavity such that a front surface on which chip pads are formed faces the lower redistribution wiring layer, and an upper redistribution wiring layer covering an upper surface of the core substrate and having upper redistribution wiring layers that are electrically connected to conductive structures of the core substrate.

### PRIORITY STATEMENT

This application claims priority under 35 U.S.C. § 119 to Korean Patent Application No. 10-2023-0048667, filed on Apr. 13, 2023 in the Korean Intellectual Property Office (KIPO), the contents of which are herein incorporated by reference in their entirety.

### BACKGROUND

### 1. Field

Example embodiments relate to a semiconductor package and a method of manufacturing the semiconductor package. More particularly, example embodiments relate to a fan out panel level package (FOPLP) and a method of manufacturing the same.

### 2. Description of the Related Art

In manufacturing a fan out panel level package (FOPLP), a semiconductor chip may be disposed in a core substrate, a sealing member covering the semiconductor chip may be formed on the core substrate, a front redistribution wiring layer may be formed on the core substrate and a lower surface of the semiconductor chip, and a backside redistribution wiring layer may be formed on the sealing member. Since the front redistribution wiring layer and the backside redistribution wiring layer are sequentially formed after the semiconductor chip is attached, there is a problem in that the semiconductor chip must be discarded when a defect occurs in forming the front redistribution wiring layer or the backside redistribution wiring layer. In addition, since all manufacturing processes must be performed sequentially, there is a problem in that lead time is long.

### SUMMARY

Example embodiments provide a semiconductor package having a structure capable of improving process yield and shortening lead time.

Example embodiments provide a method of manufacturing the semiconductor package.

According to example embodiments, a semiconductor package includes a lower redistribution wiring layer having lower redistribution wirings; an encapsulation structure on the lower redistribution wiring layer; a plurality of conductive bumps between the lower redistribution wiring layer and the encapsulation structure; and an adhesive layer attaching the lower redistribution wiring layer to the encapsulation structure, wherein the encapsulation structure includes a core substrate having a cavity formed therein; at least one semiconductor chip in the cavity such that a front surface of the at least one semiconductor chip on which chip pads are formed faces the lower redistribution wiring layer; and an upper redistribution wiring layer covering an upper surface of the core substrate and having upper redistribution wiring layers that are electrically connected to conductive structures of the core substrate.

According to example embodiments, a semiconductor package includes a lower redistribution wiring layer having lower redistribution wirings; a core substrate disposed on the lower redistribution wiring layer, the core substrate having a first surface and a second surface opposite to the first surface, the core substrate having a cavity formed therein; at least one semiconductor chip in the cavity of the core substrate on the lower redistribution wiring layer such that a front surface of the at least one semiconductor chip on which chip pads are formed faces the lower redistribution wiring layer; an upper redistribution wiring layer covering the first surface of the core substrate and having upper redistribution wirings that are electrically connected to conductive structures of the core substrate; a plurality of conductive bumps disposed between the core substrate and the lower redistribution wiring layer and between the at least one semiconductor chip and the lower redistribution wiring layer; and an adhesive layer disposed between the core substrate and the lower redistribution wiring layer and between the at least one semiconductor chip and the lower redistribution wiring layer, the adhesive layer covering side surfaces of the plurality of conductive bumps.

According to example embodiments, a semiconductor package includes a lower redistribution wiring layer having lower redistribution wirings; an encapsulation structure on the lower redistribution wiring layer, the encapsulation structure including a core substrate, at least one semiconductor chip, and an upper redistribution wiring layer, wherein the core substrate has a first surface and a second surface opposite to the first surface and has a cavity formed therein, the at least one semiconductor chip is in the cavity and a front surface of the at least one semiconductor chip on which chip pads are formed is exposed from the second surface of the core substrate, and the upper redistribution wiring layer covers the first surface of the core substrate and a portion of the at least one semiconductor chip and has upper redistribution wirings that are electrically connected to conductive structures of the core substrate; a plurality of conductive bumps between the lower redistribution wiring layer and the encapsulation structure and electrically connecting the chip pads to the lower redistribution wirings and electrically connecting the conductive structures to the lower redistribution wirings; and an adhesive layer attaching the lower redistribution wiring layer to the encapsulation structure.

According to example embodiments, a method of manufacturing a semiconductor package includes providing an encapsulation structure including a first wiring and a sealing layer, wherein a semiconductor chip including a chip pad is in a cavity formed in the encapsulation structure and covered by the sealing layer; forming a first conductive bump on the first wiring and a second conductive bump on the chip pad of the semiconductor chip; providing a lower redistribution wiring layer including a first upper bonding pad and a second upper bonding pad exposed on an upper surface of the lower redistribution wiring layer; forming an adhesive layer on the upper surface of the lower redistribution wiring layer; bonding the encapsulation structure to the lower redistribution wiring layer.

According to example embodiments, in a method of manufacturing a semiconductor package, a lower redistribution wiring layer having lower redistribution wirings is formed. A core substrate having a first surface and a second surface opposite to the first surface and having a cavity formed therein is provided. At least one semiconductor chip is disposed in the cavity such that a front surface of the at least one semiconductor chip on which chip pads are formed is exposed from the second surface of the core substrate. A sealing layer covering the first surface of the core substrate and exposing the front surface of the at least one semiconductor chip is formed. An upper insulating layer provided on the encapsulation layer and having upper redistribution wires electrically connected to the conductive structures of the core substrate is formed. A plurality of bumps are formed on the conductive structures of the core substrate and on the chip pads of the at least one semiconductor chip. An adhesive layer is formed on the lower redistribution wiring layer. The core substrate and the at least one semiconductor chip are stacked on the lower redistribution wiring layer via the plurality of bumps.

According to example embodiments, a semiconductor package as a fan out wafer level package may include a lower redistribution wiring layer, an encapsulation structure stacked on the lower redistribution wiring layer via conductive bumps, and an adhesive layer interposed between the lower redistribution wiring layer and the encapsulation structure. After the encapsulation structure including a core substrate, a semiconductor chip and an upper redistribution wiring layer is formed and the lower redistribution wiring layer is formed by a different process, the encapsulation structure may be stacked on the lower redistribution wiring layer.

Thus, defects of the lower redistribution wiring layer may be inspected in advance and the encapsulation structure may be stacked only on the lower redistribution wiring layer of a good product to minimize die loss, thereby improving process yield and shortening lead time.

### BRIEF DESCRIPTION OF THE DRAWINGS

Example embodiments will be more clearly understood from the following detailed description taken in conjunction with the accompanying drawings. FIGS. 1 to 17 represent non-limiting, example embodiments as described herein.

FIG. 1 is a cross-sectional view illustrating a semiconductor package in accordance with example embodiments.

FIG. 2 is an enlarged cross-sectional view illustrating portion ‘A’ in FIG. 1.

FIGS. 3 to 15 are views illustrating a method of manufacturing a semiconductor package in accordance with example embodiments.

FIG. 16 is a cross-sectional view illustrating a semiconductor package in accordance with example embodiments.

FIG. 17 shows a method of manufacturing a semiconductor package according to example embodiments.

### DETAILED DESCRIPTION OF EXAMPLE EMBODIMENTS

Hereinafter, example embodiments will be explained in detail with reference to the accompanying drawings.

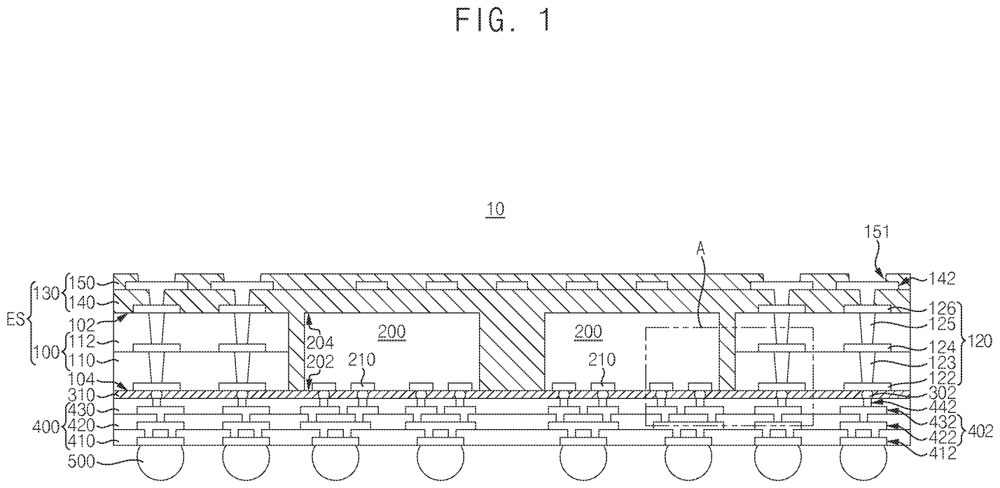

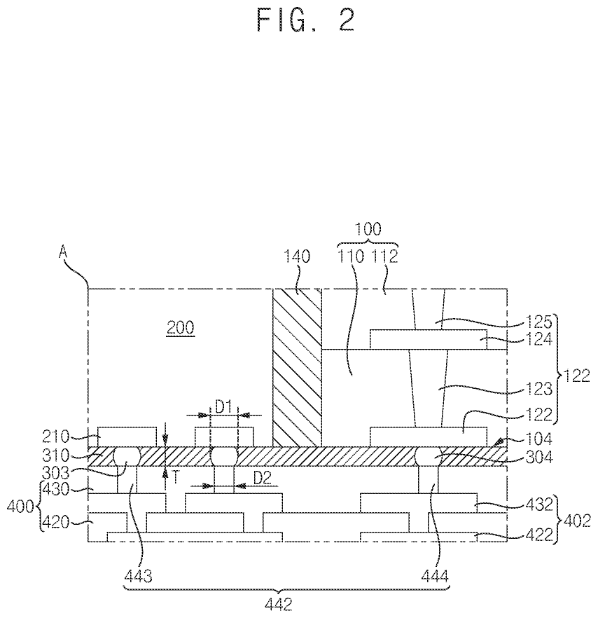

FIG. 1 is a cross-sectional view illustrating a semiconductor package in accordance with example embodiments. FIG. 2 is an enlarged cross-sectional view illustrating portion ‘A’ in FIG. 1.

Referring to FIGS. 1 and 2, a semiconductor package 10 may include a lower redistribution wiring layer 400, an encapsulation structure ES disposed on the lower redistribution wiring layer 400, a plurality of conductive bumps 302 disposed between the lower redistribution wiring layer 400 and the encapsulation structure ES, and an adhesive layer 310 attaching the lower redistribution wiring layer 400 to the encapsulation structure ES. The encapsulation structure ES may include a core substrate 100, at least one semiconductor chip 200 disposed in the core substrate 100, and an upper redistribution wiring layer 130 disposed on an upper surface of the core substrate 100. In addition, the semiconductor package 10 may further include external connection members 500 disposed on an outer surface of the lower redistribution wiring layer 400.

In example embodiments, the semiconductor package 10 may include a core substrate 100 that surrounds the semiconductor chip 200 and serves as a support member for supporting a redistribution wiring layer in a fan-out region. The core substrate 100 may serve as a frame surrounding the semiconductor chip 200. The core substrate 100 may include core connection wirings 120 as conductive connectors serving as electrical connection paths from the semiconductor chip 200 in the fan-out region outside an area where the semiconductor chip 200 is disposed. Accordingly, the semiconductor package 10 can be provided as a fan-out package. Additionally, the semiconductor package 10 may be provided as a unit package on which a second package is stacked.

Additionally, the semiconductor package 10 may be provided as a System In Package (SIP). For example, one or more semiconductor chips may be disposed on the lower redistribution wiring layer 400. The semiconductor chips may include a logic chip including a logic circuit and/or a memory chip. The logic chip may be a controller that controls memory chips. The memory chip includes various types of memory circuits, such as DRAM, SRAM, flash, PRAM, ReRAM, FeRAM, or MRAM.

In example embodiments, the lower redistribution wiring layer 400 may have first redistribution wirings 402 as lower redistribution wirings. A semiconductor chip 200 electrically connected to the first redistribution wiring layer 402 may be disposed on the lower redistribution wiring layer 400. The lower redistribution wiring layer 400 may be provided on a front surface 202 of the semiconductor chip 200 to serve as a front redistribution wiring layer. Accordingly, the lower redistribution wiring layer 400 may be a front redistribution wiring layer (FRDL) of the fan-out package.

In particular, the lower redistribution wiring layer 400 may include a plurality of lower insulating layers including first, second and third lower insulating layers 410, 420 and 430 and first redistribution wirings 402 provided in the first, second and third lower insulating layers 410, 420, and 430. The first redistribution wirings 402 may include first and second lower redistribution wirings 422 and 432.

The first, second and third lower insulating layers 410, 420, and 430 may be formed of or include a polymer or a dielectric layer. For example, the first, second and third lower insulating layers may include a photosensitive insulating layer such as PID (photo imagable dielectric), an insulating film such as ABF (Ajinomoto Build-up Film), etc. In this embodiment, the first lower insulating layer 410 may include the insulating film such as ABF (Ajinomoto Build-up Film), and the second and third lower insulating layers 420 and 430 may include photosensitive insulating films such as PID. The first, second and third lower insulating layers 410, 420, and 430 may be formed by a vapor deposition process, a spin coating process, etc. The first redistribution wirings 402 may include aluminum (Al), copper (Cu), tin (Sn), nickel (Ni), gold (Au), platinum (Pt), or an alloy thereof. The first redistribution wirings 402 may be formed by a plating process, an electroless plating process, a vapor deposition process, etc.

Lower bonding pads 412 may be provided on the first lower insulating layer 410. The lower bonding pad 412 may be a bump pad. The bump pad may include a solder pad or a pillar pad. For example, the lower bonding pad may include copper (Cu), aluminum (Al), tin (Sn), nickel (Ni), gold (Au), platinum (Pt), or an alloy thereof.

The first lower redistribution wirings 422 may be formed on the first lower insulating layer 410. The first lower redistribution wiring 422 may be electrically connected to the lower bonding pad 412 through a first opening formed in the first lower insulating layer 410.

The second lower insulating layer 420 may be formed on the first lower insulating layer 410 and may cover the first lower redistribution wirings 422. The second lower redistribution wirings 432 may be formed on the second lower insulating layer 420. The second lower redistribution wiring 432 may be electrically connected to the first lower redistribution wiring 422 through a second opening formed in the second lower insulating layer 420.

The third lower insulating layer 430 may be formed on the second lower insulating layer 420 and may cover the second lower redistribution wirings 432. Upper bonding pads 442 may be provided on the third lower insulating layer 430. The upper bonding pads 442 may be respectively provided on the second lower redistribution wirings 432. Via holes may be formed in the third lower insulating layer 430 to expose portions of the second lower redistribution wirings 432. The upper bonding pad 442 may be electrically connected to the second lower redistribution wiring 432 through the via holes in the third lower insulating layer 430.

The number and arrangement of the lower insulating layers and the lower redistribution wirings of the lower redistribution wiring layer are provided as examples, and it will be understood that the present inventive concept is not limited thereto.

In example embodiments, when viewed from a plan view, the lower redistribution wiring layer 400 may include a first region that overlaps the semiconductor chip 200 mounted on an upper surface of the lower redistribution wiring layer 400 and a second region surrounding the first region. The second region may be a fan-out region outside the area where the semiconductor chip 200 is disposed.

The upper bonding pads 442 may be exposed from the upper surface of the lower redistribution wiring layer 100, that is, the third lower insulating layer 430. The upper bonding pads 442 may include chip connection bonding pads 443 that are formed on uppermost first redistribution wirings, that is, the second lower redistribution wirings 432 located in the first region and conductive structure connection bonding pads 444 that are formed on the uppermost first redistribution wirings, that is, the second lower redistribution wirings 432 in the second region.

In example embodiments, the encapsulation structure ES may include the core substrate 100, the at least one semiconductor chip 200 disposed in the core substrate 100 and the upper redistribution wiring layer 130 disposed on an upper surface of the core substrate 100.

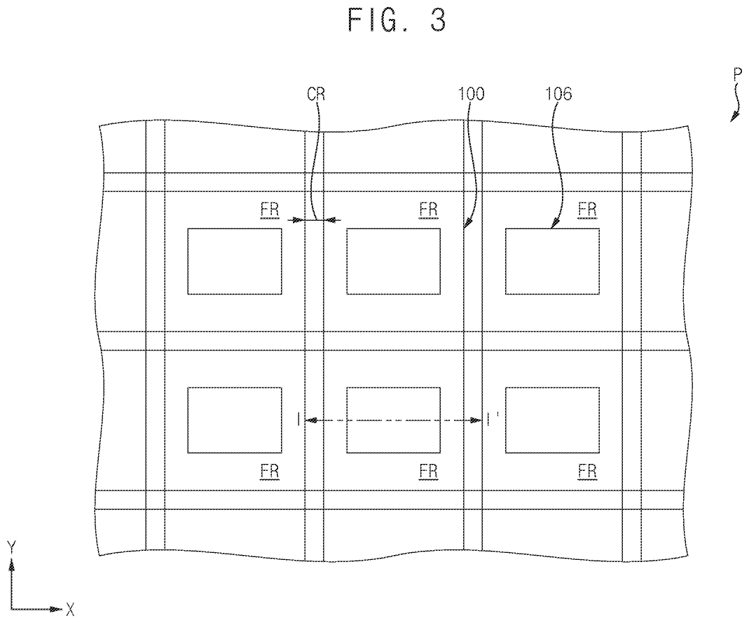

In particular, the core substrate 100 may have a first surface (upper surface) 102 and a second surface (lower surface) 104 opposite to the first surface 102. The core substrate 100 may have at least one cavity 106 (see, e.g., FIG. 3) in a central portion thereof. The cavity 106 may extend from the first surface 102 to the second surface 104 of the core substrate 100.

The core substrate 100 may include a plurality of stacked insulating layers 110 and 112 and core connection wirings 120 in the insulating layers. The plurality of core connection wirings 120 may be provided in a fan-out region outside the area where the semiconductor chip (die) is disposed and may be used for electrical connection with the mounted semiconductor chip. The core connection wiring 120 may be a vertical connection structure penetrating the core substrate 100 from the first surface 102 to the second surface 104 of the core substrate 100.

For example, the core substrate 100 may include a first insulating layer 110 and a second insulating layer 112 stacked on the first insulating layer 110. The core connection wiring 120 may include a first wiring 122, a first contact 123, a second wiring 124, a second contact 125 and a third wiring 126. The first wiring 122 may be provided on the second surface 104 of the core substrate 100, that is, a lower surface of the first insulating layer 110, and at least a portion of the first wiring 122 may be exposed from the second surface 104. The third wiring 126 may be provided on the first surface 102 of the core substrate 100, that is, an upper surface of the second insulating layer 112, and at least a portion of the third wiring 126 may be exposed from the first surface 102. The numbers and arrangements of the insulating layers and the core connection wirings of the core substrate 100 are provided as examples, and it will be understood that the present inventive concept is not limited thereto.

In example embodiments, the at least one semiconductor chip 200 may be disposed in the cavity 106 of the core substrate 100. Two semiconductor chips 200 may be disposed in one cavity 106. A sidewall of the semiconductor chip 200 may be spaced apart from an inner wall of the cavity 106. Accordingly, a gap may be formed between the sidewall of the semiconductor chip 200 and the inner wall of the cavity 106. Alternatively, the core substrate 100 may include two cavities, and two semiconductor chips 200 may be disposed in the two cavities respectively.

The semiconductor chip 200 may include a substrate and chip pads 210 on a front surface 202 of the substrate, that is, an active surface. The front surface 202 of the semiconductor chip 200 on which the chip pads 210 are formed may face the lower redistribution wiring layer 400. Accordingly, the chip pads 210 may be exposed from the second surface 104 of the core substrate 100. The front surface 202 of the semiconductor chip 200 may be positioned on the same plane as the second surface 104 of the core substrate 100. A backside surface 204 opposite to the front surface 202 of the semiconductor chip 200 may be positioned higher than the first surface 102 of the core substrate 100, but the inventive concept is not limited thereto. A thickness of the semiconductor chip 200 may be greater than a thickness of the core substrate 100, but the inventive concept is not limited thereto. The thickness of the semiconductor chip 200 may be within a range of 60 μm to 150 μm, and the thickness of the core substrate 100 may be within a range of 50 μm to 140 μm.

Although only a few chip pads are illustrated in the drawings, the structures and arrangements of the chip pads are provided as examples, and it will be understood that the present inventive concept is not limited thereto. Additionally, although only two semiconductor chips are illustrated, the inventive concept is not limited thereto, and one or three or more semiconductor chips may be disposed in the core substrate 100.

In example embodiments, the upper redistribution wiring layer 130 may include a sealing layer 140 and at least one upper insulating layer 150. The upper redistribution wiring layer 130 may include second redistribution wirings 142 as upper redistribution wirings. The second redistribution wirings 142 may be provided on the backside surface 204 of the semiconductor chip 200 and the first surface 102 of the core substrate 100 to serve as upper redistribution wirings. Accordingly, the upper redistribution wiring layer 130 may be a backside redistribution wiring layer (BRDL) of the fan-out package.

In particular, the sealing layer 140 may be provided on the first surface 102 of the core substrate 100 to fill the cavity 106 and to cover the backside surface 204 of the semiconductor chip 200. The sealing layer 140 includes a first sealing portion that covers the first surface 102 of the core substrate 100, a second molding portion that covers the backside surface 204 of the semiconductor chip 200, and a third molding portion that fills the gap between the side surface of semiconductor chip 200 and the inner wall of the cavity 106. The sealing layer 140 may have openings that expose the third wirings 126 of the core connection wiring 120.

For example, the sealing layer 140 may be formed of or include a thermosetting resin such as epoxy resin, a thermoplastic resin such as polyimide, or a resin including a reinforcing material such as inorganic fillers. In particular, the sealing layer may include an insulating film such as ABF (Ajinomoto Build-up Film), a composite material such as FR-4, and a resin such as BT (Bismaleimide Triazine). In addition, the sealing layer may include a molding material such as EMC (Epoxy Molding Compound), a photosensitive insulating material such as PIE (Photo Imagable Encapsulant), etc. When the sealing layer 140 includes an insulating film such as ABF, the sealing layer 140 may be formed by a lamination process.

The upper redistribution wirings 142 may be provided on the sealing layer 140 and may directly contact the third wirings 126 through the openings formed in the sealing layer 140. Accordingly, the upper redistribution wirings 142 may be electrically connected to the core connection wirings 120 respectively. The upper insulating layer 150 may be provided on the sealing layer 140 and may cover the upper redistribution wirings 142.

For example, the upper redistribution wirings 142 may be formed of or include copper (Cu), aluminum (Al), tin (Sn), nickel (Ni), gold (Au), platinum (Pt), or an alloy thereof. The upper insulating layer 150 may include an insulating film such as ABF, which is the same as the sealing layer 140.

The upper insulating layer 150 may have openings 151 that expose at least portions of the upper redistribution wirings 142. A bonding pad may be provided on a portion of the upper redistribution wiring 142 exposed by the opening 151. A passivation layer may be provided on the upper insulating layer 150 and may expose a portion of the bonding pad.

The number, arrangement, etc. of the upper insulating layer 150 and the upper redistribution wirings 142 of the upper redistribution wiring layer 130 are provided as examples, and it will be understood that the present inventive concept is not limited thereto.

The upper redistribution wirings 142 are illustrated as including the first redistribution wirings formed in one layer on the sealing layer 140, but may not be limited thereto. For example, the upper redistribution wirings 142 may include first upper redistribution wirings and second upper redistribution wirings stacked in at least two layers. In this case, the first upper redistribution wiring may correspond to the upper redistribution wiring 142 and the second upper redistribution wiring may correspond to an uppermost redistribution wiring. Bonding pads may be formed on the second upper redistribution wirings by a subsequent process.

In example embodiments, the encapsulation structure ES including the core substrate 100, the at least one semiconductor chip 200 and the upper redistribution wiring layer 130 may be stacked on the lower redistribution wiring layer 400 via conductive bumps 302.

The conductive bumps 302 may be interposed between the encapsulation structure ES and the lower redistribution wiring layer 400. The conductive bumps 302 may be interposed between the core substrate 100 and the lower redistribution wiring layer 400 and between the semiconductor chip 200 and the lower redistribution wiring layer 400. The conductive bumps 302 may electrically connect the conductive structure 120 of the core substrate 100 to the lower redistribution wirings 402 of the lower redistribution wiring layer 400. The conductive bumps 302 may electrically connect the chip pads 210 of the semiconductor chip 200 to the lower redistribution wirings 402 of the lower redistribution wiring layer 400.

The encapsulation structure ES may be stacked on the lower redistribution wiring layer 400 such that the front surface 202 of the semiconductor chip 200 and the second surface 104 of the core substrate 100 face the lower redistribution wiring layer 400.

In example embodiments, the encapsulation structure ES may be attached to the lower redistribution wiring layer 400 using an adhesive layer 310. The adhesive layer 310 serving as a gap fill material layer may be filled between the encapsulation structure ES and the lower redistribution wiring layer 400. The adhesive layer 310 may cover side surfaces of the conductive bumps 302.

For example, the adhesive layer 310 may be formed of or include a non-conductive film (NCF). Bumps on the chip pads 210 of the semiconductor chip 200 and the first wirings 122 of the conductive structure 120 may be reflowed by thermal compression of a bonding apparatus to form the conductive bumps 302 and the encapsulation structure ES may be attached on the lower redistribution wiring layer 400 by the adhesive layer 310.

As illustrated in FIG. 2, the conductive bumps 302 may include first conductive bumps 303 and second conductive bumps 304. The first conductive bumps 303 are formed on the chip pads 210 of the semiconductor chip 200, and the second conductive bumps 304 may be formed on the first wirings 122 of the conductive structure 120 of the core substrate 100.

The first conductive bump 303 may be disposed between the chip connection bonding pad 443 among the upper bonding pads 422 and the chip pad 210 of the semiconductor chip 200. Accordingly, the chip pads 210 of the semiconductor chip 200 may be electrically connected to the first redistribution wirings 402 of the lower redistribution wiring layer 400 by the first conductive bumps 303.

The second conductive bump 304 may be disposed between the conductive structure connecting pad 444 among the upper bonding pads 422 and the conductive structure 120 of the core substrate 100. Accordingly, the conductive structures 120 of the core substrate 100 may be electrically connected to the first redistribution wirings 402 of the lower redistribution wiring layer 400 by the second conductive bumps 304.

For example, as shown, e.g., in FIG. 2, the conductive bump 302 may have a diameter D1 within a range of 5 μm to 60 μm. A diameter D2 of the upper bonding pad 442 may be the same as a diameter D1 of the conductive bump 302. Alternatively, the diameter D2 of the upper bonding pad 442 may be larger or smaller than the diameter D1 of the conductive bump 302.

The third lower insulating layer 430 may include via holes that expose portions of the second lower redistribution wirings 432, and the upper bonding pads 442 may be provided in the via holes of the third lower insulating layer 430. The upper bonding pad 442 may have a pillar shape corresponding to the via hole.

In example embodiments, the external connection members 500 may be disposed on lower bonding pads 412 on the outer surface of the lower redistribution wiring layer 400. For example, the external connection member 500 may include a solder ball. The solder ball may have a diameter of 300 μm to 500 μm. The semiconductor package 10 may be mounted on a module substrate via the solder balls to form a memory module.

As mentioned above, the semiconductor package 10 as a fan-out wafer level package may include the lower redistribution wiring layer 400, the encapsulation structure ES stacked on the lower redistribution wiring layer 400 via the conductive bumps 302, and the adhesive layer 310 interposed between the lower redistribution wiring layer 400 and the encapsulation structure ES. The encapsulation structure ES may include the core substrate 100, the at least one semiconductor chip 200 disposed in the core substrate 100, and the upper redistribution wiring layer 130 disposed on the upper surface of the core substrate 100. The conductive structures 120 of the core substrate 100 and the chip pads 210 of the semiconductor chip 200 may be electrically connected to the lower redistribution wirings 402 of the lower redistribution wiring layer 400 by the conductive bumps 302. The upper redistribution wirings 142 of the upper redistribution wiring layer 130 may be electrically connected to the conductive structures 120 of the core substrate 100.

After the encapsulation structure ES including the core substrate 100, the semiconductor chip 200 and the upper redistribution wiring layer 130 is formed, and the lower redistribution wiring layer 400 is formed in a different process, the encapsulation structure ES may be stacked on the lower redistribution wiring layer 400 via the conductive bumps 302 as a medium.

Thus, defects of the lower redistribution wiring layer 400 may be inspected in advance and the encapsulation structure ES may be stacked only on the lower redistribution wiring layer of a good product to minimize die loss, thereby improving process yield and shortening lead time.

Hereinafter, a method of manufacturing the semiconductor package of FIG. 1 will be described.

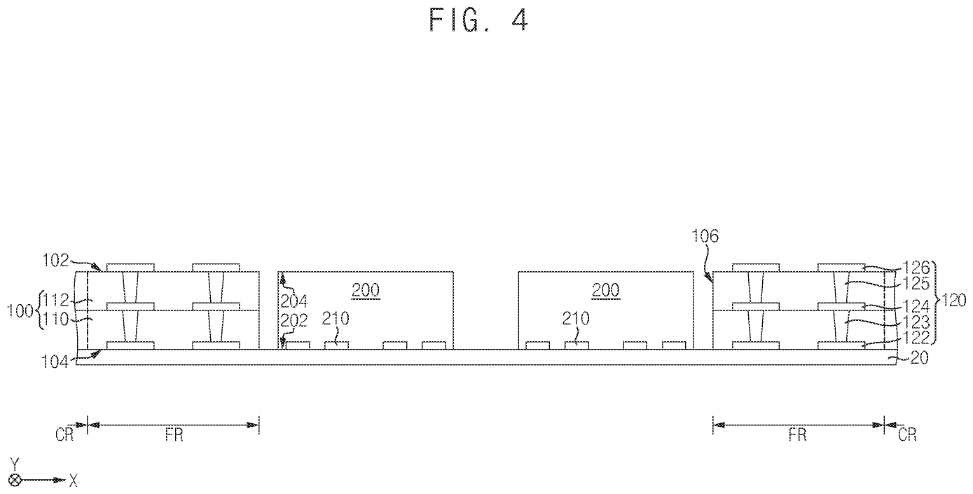

FIGS. 3 to 15 are views illustrating a method of manufacturing a semiconductor package in accordance with example embodiments. FIG. 3 is a plan view illustrating a panel in which a plurality of core substrates is formed. FIGS. 4 to 15 are cross-sectional views taken along line I-I′ in FIG. 3.

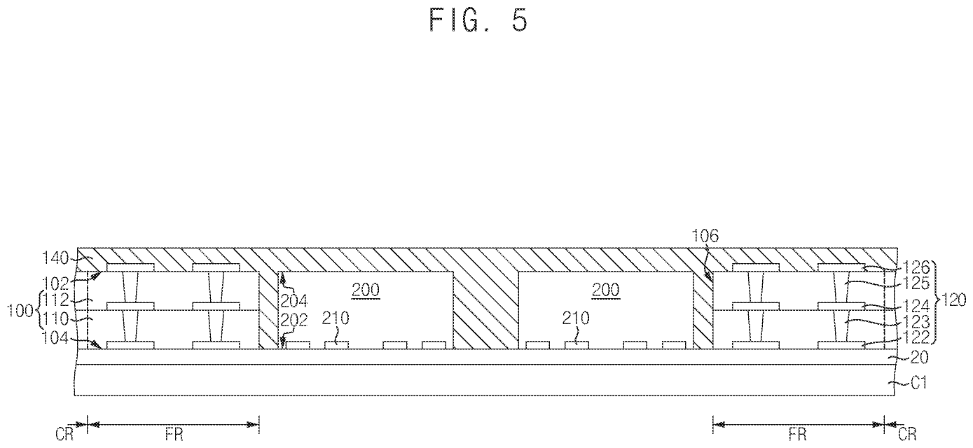

Referring to FIGS. 3 to 5, first, a panel P on which a plurality of core substrates 100 is formed may be prepared, at least one semiconductor chip 200 may be placed in a cavity 106 of the core substrate 100, and a sealing layer 140 (see, e.g., FIG. 5) may be formed to cover the semiconductor chip 200.

In example embodiments, the core substrate 100 may be used as a base substrate as a support member for electrical connection on which the semiconductor chip 200 is arranged to form a semiconductor package having a fan-out panel level package configuration.

As illustrated in FIG. 3, the panel P may include a frame region FR for the core substrate 100 and a scribe lane region surrounding the frame region FR, that is, a cutting region CR. As will be described below, the panel P may be cut along the cutting region CR dividing the frame regions FR from each other to be divided into individual core substrates 100.

As illustrated in FIG. 4, the core substrate 100 may have a first surface 102 and a second surface 104 opposite to the first surface 102. The core substrate 100 may have a cavity 106 in a central portion thereof. The cavity 106 may have a planar area for accommodating at least one semiconductor chip 200. Alternatively, the core substrate 100 may have a plurality of cavities in the central portion, and one or more semiconductor chips may be disposed in each of the plurality of cavities.

The core substrate 100 may include a plurality of stacked insulating layers 110 and 112 and core connection wirings 120 as conductive connection structures provided in the insulating layers. The plurality of core connection wirings 120 may be provided to penetrate the core substrate 100 from the first surface 102 to the second surface 104 of the core substrate 100 to serve as electrical connection passages, respectively. That is, the core connection wirings 120 may be provided in a fan-out area outside an area where the semiconductor chip (die) is disposed and may be used for electrical connection. For example, the core connection wiring 120 may include a first wiring 122, a first contact 123, a second wiring 124, a second contact 125 and a third wiring 126. Alternatively, the core connection wiring may include a through via penetrating the core substrate.

Then, after the panel P may be disposed on a barrier tape 20, at least one semiconductor chip 200 may be disposed in the cavity 106.

The second surface 104 of the core substrate 100 may be attached on the barrier tape 20. For example, dies (chips) may be disposed in hundreds to thousands of cavities 106 of the panel P, respectively. As will be described below, a singulation process may be performed to cut the panel P along the cutting region CR, to complete individual fan-out panel level packages.

In this embodiment, two semiconductor chips 200 may be disposed in one cavity 106. The two semiconductor chips 200 may be spaced apart from each other along a first direction (X direction).

The semiconductor chip 200 may include a substrate and chip pads 210 provided on a front surface 202 of the substrate, that is, an active surface. The semiconductor chip 200 may be disposed such that the front surface of the semiconductor chip 200 on which the chip pads 210 are formed faces the barrier tape 20. The front surface 202 of the semiconductor chip 200 may be positioned on the same plane as the second surface 104 of the core substrate 100. The semiconductor chip 200 may be disposed in the cavity 106 of the core substrate 100. A sidewall of the semiconductor chip 200 may be spaced apart from an inner wall of the cavity 106. Thus, a gap may be formed between the sidewall of the semiconductor chip 200 and the inner wall of the cavity 106.

A thickness of the semiconductor chip 200 may be smaller than a thickness of the core substrate 100. Accordingly, a backside surface 204 of the semiconductor chip 200 may be positioned lower than the first surface 102 of the core substrate 100. Alternatively, the thickness of the semiconductor chip 200 may be equal to or greater than the thickness of the core substrate 100. In this case, the backside surface 204 of the semiconductor chip 200 may be positioned on the same plane as or higher than the first surface 102 of the core substrate 100.

As illustrated in FIG. 5, after the core substrate 100 and the barrier tape 20 are disposed on a first carrier substrate C1, a sealing layer 140 may be formed on the first surface 102 of the core substrate 100 to cover the semiconductor chip 200.

The sealing layer 140 may be formed to fill a gap between the sidewall of the semiconductor chip 200 and the inner wall of the cavity 106. Accordingly, the backside surface 204 of the semiconductor chip 200, the first surface 102 of the core substrate 100 and the inner wall of the cavity 106 may be covered by the sealing layer 140.

For example, the sealing layer 140 may be formed of or include an insulating film such as ABF (Ajinomoto Build-up Film), an insulating material (thermosetting dielectric material) such as epoxy resin, a photosensitive insulating material such as photo imagable dielectric (PID), etc. When the sealing layer 140 includes the insulating film such as ABF, the sealing layer 140 may be formed by a lamination process.

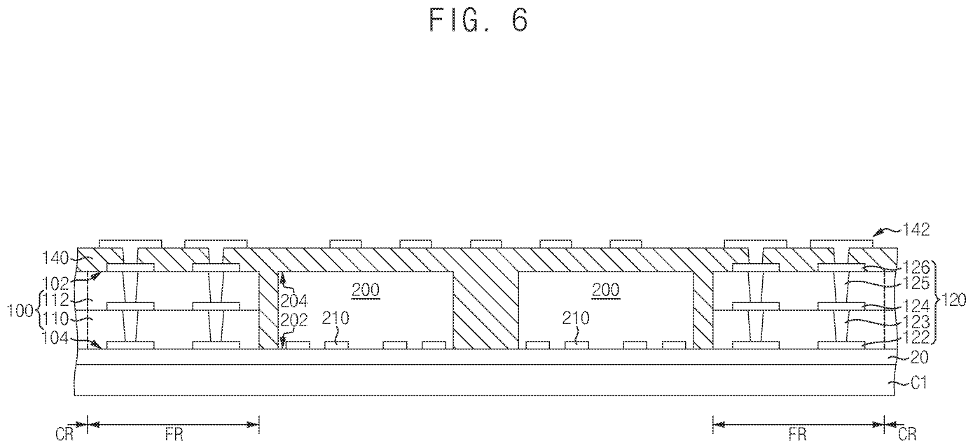

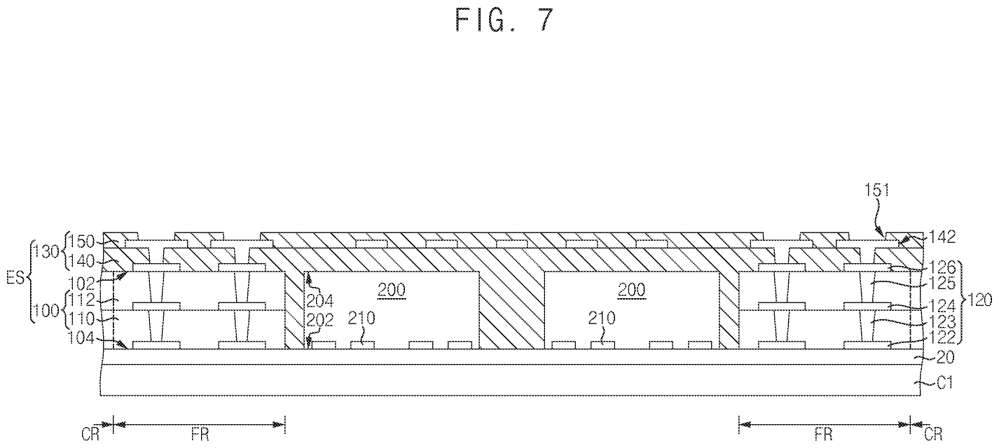

Referring to FIGS. 6 and 7, at least one upper insulating layer 150 having upper redistribution wirings 142 may be formed on the sealing layer 140 on the first surface 102 of the core substrate 100 and the backside surface 204 of the semiconductor chip 200. The upper redistribution wirings 142 may be electrically connected to the core connection wirings 120.

As illustrated in FIG. 6, the sealing layer 140 on the first surface 102 of the core substrate 100 may be partially removed to form openings that expose the third wirings 126 of the core connection wirings 120, and the upper redistribution wirings 142 may be formed on the sealing layer 140. The upper redistribution wirings 142 may be electrically connected to the core connection wirings 120 through the openings.

As illustrated in FIG. 7, after the upper insulating layer 150 is formed on the sealing layer 140, the upper insulating layer may be partially removed to form openings 151 that expose the upper redistribution wirings 142. The upper insulating layer may include an insulating film such as ABF that is the same as the sealing layer 140.

The upper redistribution wirings 142 are illustrated as including the first redistribution wirings formed in one layer on the sealing layer 140, but may not be limited thereto. For example, the upper redistribution wirings 142 may include first upper redistribution wirings and second upper redistribution wirings stacked in at least two layers. In this case, the first upper redistribution wiring may correspond to the upper redistribution wiring 142 and the second upper redistribution wiring may correspond to an uppermost redistribution wiring. Bonding pads may be formed on the second upper redistribution wirings by a following process. For example, the first and second upper redistribution wirings may be formed of or include copper (Cu), aluminum (Al), tin (Sn), nickel (Ni), gold (Au), platinum (Pt), or alloys thereof.

In one embodiment, second upper redistribution wirings may be formed on the upper insulating layer to be electrically connected to the first upper redistribution wirings 142 through openings 151, and a second upper insulating layer may be formed on the upper insulating layer to cover the second upper redistribution wirings. Then, the second upper insulating layer may be partially removed to form openings that expose the second upper redistribution wirings. In this case, the upper redistribution wirings may include the first upper redistribution wirings 142 and the second upper redistribution wirings stacked in two layers, and the second upper redistribution wirings may correspond to the uppermost redistribution wirings among the upper redistribution wirings.

Then, bonding pads may be formed on the upper redistribution wirings 142. For example, the bonding pad may be formed on the upper redistribution wiring 142 exposed by the opening 151 and a passivation layer may be formed on the upper insulating layer 150 to expose a portion of the bonding pad.

Accordingly, an encapsulation structure ES including the core substrate 100 in which the semiconductor chips 200 are accommodated, and an upper redistribution wiring layer 130 having the sealing layer 140 covering the first surface 102 of the core substrate 100 and the upper insulating layer 150 provided on the sealing layer 140 may be formed.

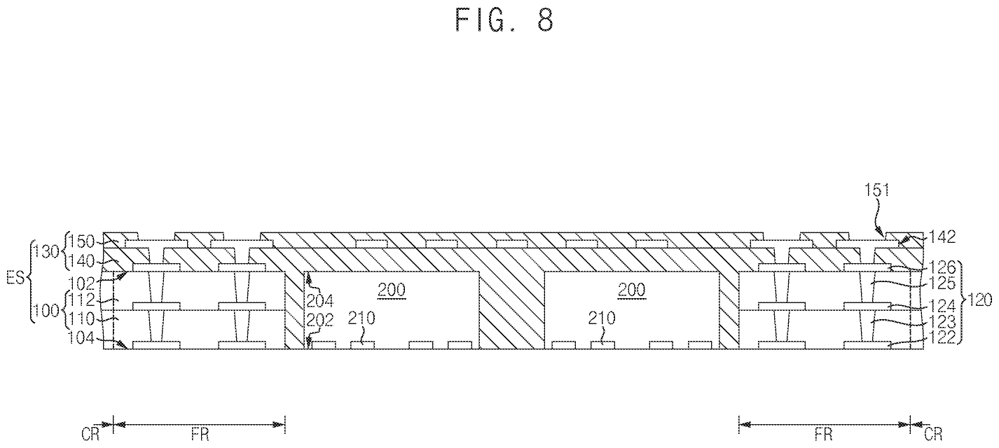

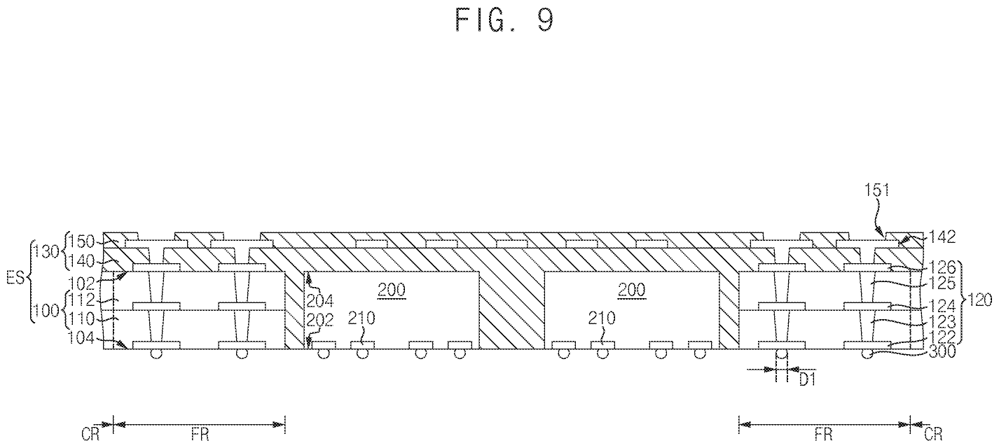

Referring to FIGS. 8 and 9, conductive bumps 300 may be formed on the chip pads 210 of the semiconductor chips 200 and the first wirings 122 of the core connection wirings 120 of the encapsulation structure ES.

As illustrated in FIG. 8, the first carrier substrate C1 and the barrier tape 20 may be removed from the core substrate 100 and the sealing layer 140. Thus, the second surface 104 of the core substrate 100 and the front surface 202 of the semiconductor chip 200 may be exposed.

As illustrated in FIG. 9, the bumps 300 may be formed on the exposed second surface 104 of the core substrate 100 and the exposed front surface 202 of the semiconductor chip 200. The bumps 300 may include micro bumps. For example, the bumps 300 may have a diameter D1 within a range of 5 μm to 60 μm.

In particular, a seed layer may be formed on the second surface 104 of the core substrate 100 and the front surface 202 of the semiconductor chip 200, and a photoresist pattern having openings that expose bump regions on the first wirings 122 and the chip pads 210 may be formed on the seed layer. Then, after filling the opening of the photoresist pattern with a conductive material, the photoresist pattern may be removed and a reflow process may be performed to form the bump 300. For example, the conductive material may be formed on the seed layer by a plating process. Alternatively, the bumps may be formed by a screen printing process, a deposition process, etc.

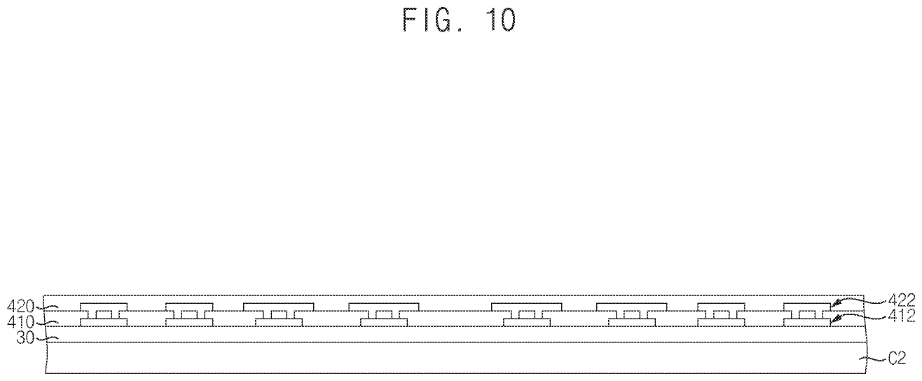

Referring to FIGS. 10 to 12, a lower redistribution wiring layer 400 having lower redistribution wirings 402 may be formed on a second carrier substrate C2.

In example embodiments, the second carrier substrate C2 may be used as a base substrate for bonding the encapsulation structure on the lower redistribution wiring layer. The second carrier substrate C2 may have a shape corresponding to the panel including the core substrate. For example, the second carrier substrate C2 may include a silicon substrate, a glass substrate, a non-metal or metal plate, etc.

As illustrated in FIG. 10, lower bonding pads 412 and first lower redistribution wirings 422 electrically connected to the lower bonding pads 412 may be formed on the second carrier substrate C2.

In particular, after forming a base insulating layer 30 on the second carrier substrate C2, the lower bonding pads 412 may be formed on the base insulating layer 30. For example, the base insulating layer 30 and the first lower insulating layer 410 may be formed of or include a polymer or a dielectric layer. The base insulating layer 30 and the first lower insulating layer 410 may include an insulating film such as ABF. The lower bonding pad 412 may be a bump pad. The bump pad may include a solder pad or a pillar pad. For example, the lower bonding pad may include copper (Cu), aluminum (Al), tin (Sn), nickel (Ni), gold (Au), platinum (Pt), or an alloy thereof.

Then, a first lower insulating layer 410 is formed on the base insulating layer 30 to cover the lower bonding pads 412, and the first lower insulating layer 410 may be patterned to form first openings that expose regions of the lower bonding pad 412. When the first lower insulating layer 410 includes the insulating film such as ABF, a laser processing process may be performed on the first lower insulating layer 410 to form the first openings that expose the lower bonding pad regions.

Then, first lower redistribution wirings 422 may be formed on the first lower insulating layer 410 to directly contact the lower bonding pads 412 through the first openings.

The first lower redistribution wiring may be formed by forming a seed layer on a portion of the first lower insulating layer 410 and in the first opening, patterning the seed layer, and performing an electroplating process. Accordingly, at least portions of the first lower redistribution wirings 422 may directly contact the lower bonding pads 412 through the first openings.

For example, the first lower redistribution wiring may include copper (Cu), aluminum (Al), tin (Sn), nickel (Ni), gold (Au), platinum (Pt), or an alloy thereof.

Then, a second lower insulating layer 420 may be formed on the first lower insulating layer 410 to cover the first lower redistribution wirings 422.

For example, the second lower insulating layer 420 may include a polymer or a dielectric layer. The second lower insulating layer 420 may include a photosensitive insulating material (PID) or an insulating film such as ABF. The second lower insulating layer may be formed by a spin coating process, a vapor deposition process, etc.

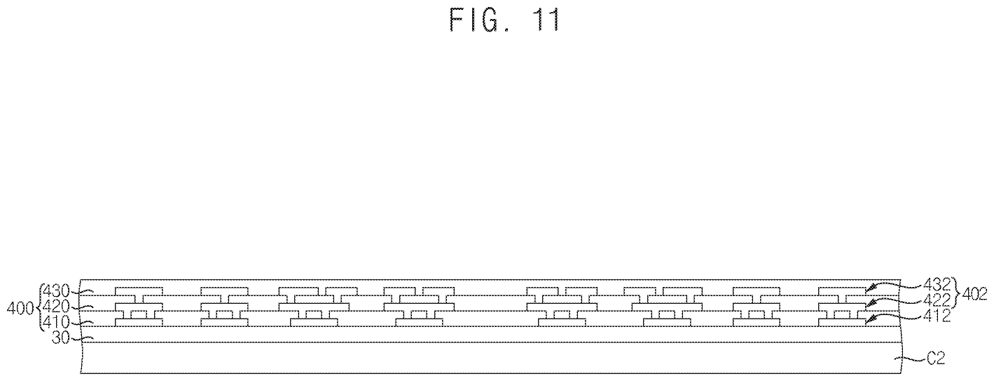

As illustrated in FIG. 11, the second lower insulating layer 420 may be patterned to form second openings that expose the first lower redistribution wirings 422. Then, second lower redistribution wirings 432 may be formed on the second lower insulating layer 420 to directly contact the first lower redistribution wirings 422 through the second openings. Accordingly, the lower redistribution wirings 402 including the first lower redistribution wirings 422 and the second lower redistribution wirings 432 may be formed. The first lower redistribution wiring 422 may correspond to a lowermost redistribution wiring among the lower redistribution wirings 402, and the second lower redistribution wiring 432 may correspond to an uppermost redistribution wiring of the lower redistribution wirings 402.

Then, a third lower insulating layer 430 may be formed on the second lower insulating layer 420 to cover the second lower redistribution wirings 432.

For example, the third lower insulating layer 430 may be formed of or include a polymer or a dielectric layer. The third lower insulating layer 430 may include a photosensitive insulating material (PID) or an insulating film such as ABF. The third lower insulating layer may be formed by a spin coating process, a vapor deposition process, etc.

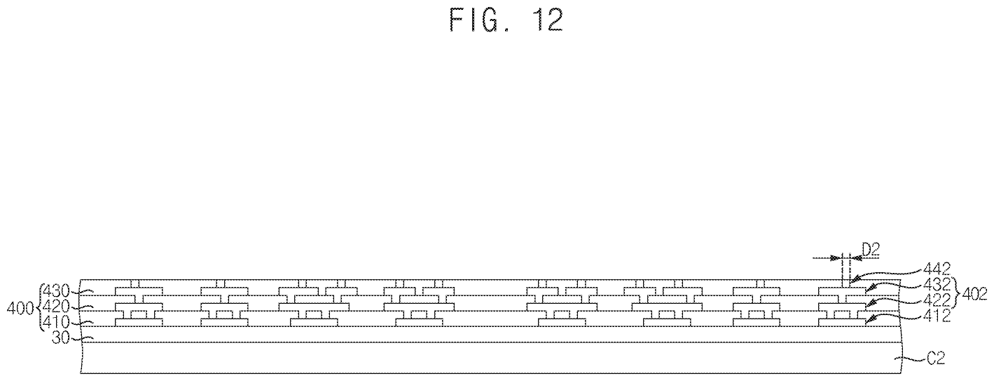

As illustrated in FIG. 12, upper bonding pads 442 may be formed to be electrically connected to the second lower redistribution wirings 432. The upper bonding pads 442 may be formed on the uppermost redistribution wirings 432 among the lower redistribution wirings 402.

In example embodiments, when the third lower insulating layer 430 includes the photosensitive insulating material (PID), an exposure process and a developing process may be sequentially performed on the third lower insulating layer 430 to form via holes that expose portions of the second lower redistribution wirings 432.

For example, a mask may be disposed on the third lower insulating layer 430 and light may be irradiated onto the mask. The mask may have an opening pattern corresponding to the bumps 300 on a lower surface of the encapsulation structure ES of FIG. 9.

Then, an electroplating process may be performed to fill the via holes of the third lower insulating layer 430 with a conductive material, to form the upper bonding pads 442. An upper surface of the upper bonding pad 442 may be exposed by the third lower insulating layer 430. A plating pattern for bonding with the bump 300 may be additionally provided on the upper surface of the upper bonding pad 442. For example, the upper bonding pad 442 may have a diameter D2 within a range of 5 μm to 60 μm. The diameter D2 of the upper bonding pad 442 may be the same as the diameter D1 of the bump 300. The upper bonding pad 442 may have a pillar shape.

Accordingly, the lower redistribution wiring layer 400 having the first redistribution wirings 402 and the lower bonding pads 412 and the upper bonding pads 442 electrically connected to the first redistribution wirings 402 may be formed.

When viewed from a plan view, the lower redistribution wiring layer 400 may include a first region overlapping the semiconductor chip 200 mounted on the upper surface of the lower redistribution wiring layer 400 and a second region surrounding the first region. The second region may be a fan-out region outside the area where the semiconductor chip 200 is disposed.

The upper bonding pads 442 may be exposed from an upper surface of the lower redistribution wiring layer 100, that is, the third lower insulating layer 430. The upper bonding pads 442 may include chip connection bonding pads formed on the uppermost first redistribution wirings, that is, the second lower redistribution wirings 432 located in the first region, and conductive structure connection bonding pads formed on the uppermost first redistribution wirings, that is, the second lower redistributions 432 located in the second region.

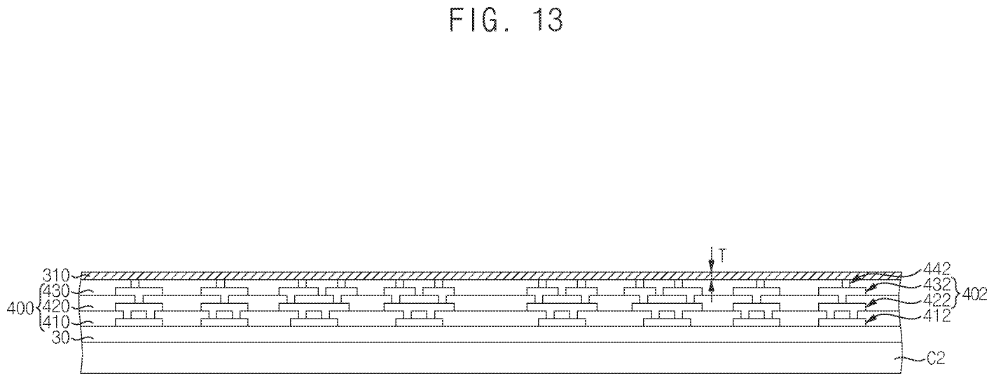

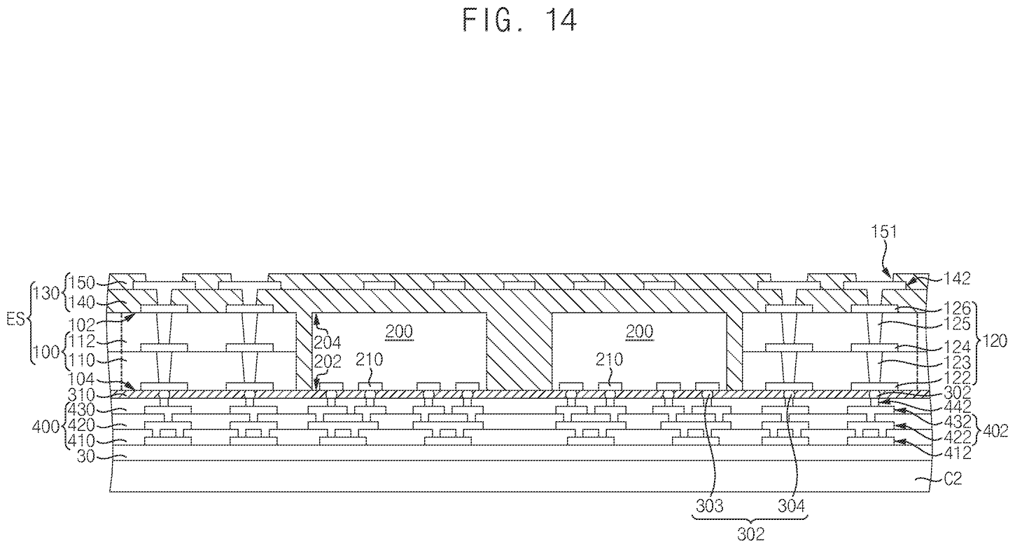

Referring to FIGS. 13 and 14, the encapsulation structure ES of FIG. 9 may be stacked on the lower redistribution wiring layer 400. The encapsulation structure ES may be attached to the lower redistribution wiring layer 400 using an adhesive layer 310.

As illustrated in FIG. 13, the adhesive layer 310 may be formed on the third lower insulating layer 430 of the lower redistribution wiring layer 400. For example, the adhesive layer 310 may be formed of or include a non-conductive film (NCF). The adhesive layer 310 may have a thickness T within a range of 5 μm to 50 μm. The thickness T of the adhesive layer 310 may be determined in consideration of the diameter D1 of the bump 300. A ratio (T/D1) of the thickness T to the diameter D1 may be within a range of 0.8 to 0.9. The micro bumps 300 may undesirably fail to connect to the lower redistribution wiring layer 400 if the adhesive layer 310 is too thick and the adhesive layer 310 may fail to provide adequate adhesion if its thickness is too small. As the number of the bumps increases, a pitch between the bumps decreases, and accordingly, the diameter of the bump may decrease. The adhesive layer 310 may be used to attach the encapsulation structure ES to the lower redistribution wiring layer 400 via the bumps 300.

As illustrated in FIG. 14, the lower redistribution wiring layer 400 may be held on a stage of a bonding apparatus, the encapsulation structure ES of FIG. 9 may be adsorbed on a head of the bonding apparatus, and the encapsulation structure ES may be bonded on the lower redistribution wiring layer 400 by a thermal compression process.

The adhesive layer 310 may be heated and the bumps 300 may be reflowed to form conductive bumps 302 between the first wiring 122 of the core substrate 100 and the upper bonding pad 442 and between the chip pad 210 of the semiconductor chip 200 of the core substrate 100 and the upper bonding pads 442.

The conductive bumps 302 may include first conductive bumps 303 and second conductive bumps 304. The first conductive bumps 303 may be disposed between the chip connection bonding pad 443 among the upper bonding pads 442 and the chip pad 210 of the semiconductor chip 200. The second conductive bump 304 may be disposed between the conductive structure connection bonding pad 444 among the upper bonding pads 442 and the conductive structure 120 of the core substrate 100.

Additionally, the adhesive layer 310 may be formed to fill a gap between the conductive bumps 302 between the lower surface of the encapsulation structure ES and the lower redistribution wiring layer 400. The adhesive layer 310 may cover side surfaces of the conductive bumps 302.

Thus, the encapsulation structure ES may be stacked on the lower redistribution wiring layer 400 via the conductive bumps 302.

In example embodiments, before stacking the encapsulation structure ES on the lower redistribution wiring layer, defects of the lower redistribution wiring layer may be inspected in advance. By stacking the encapsulation structure only on a good lower redistribution wiring layer, it may be possible to minimize die loss and improve process yield.

Further, the lead time may be shortened by simultaneously performing the process of forming the encapsulation structure ES and the process of forming the lower redistribution wiring layer 400.

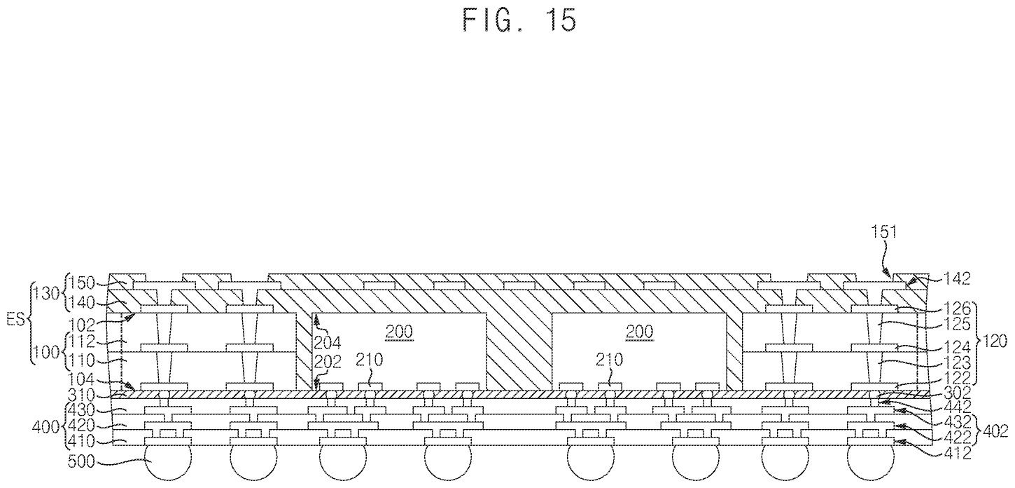

Referring to FIG. 15, external connection members 500 electrically connected to the lower redistribution wiring layers 402 may be formed on an outer surface of the lower redistribution wiring layer 400.

In example embodiments, after removing the second carrier substrate, solder balls as the external connection member may be formed on the lower bonding pads 412. After removing the second carrier substrate C2, the base insulating layer 30 may be removed. Alternatively, after removing the second carrier substrate C2, the base insulating layer 30 may be partially removed to expose portions of the lower bonding pads 412. In this case, the lower bonding pad 412 may serve as a landing pad, that is, a package pad.

Then, the core substrate 100 may be individualized by a sawing process to complete the fan out panel level package 10 of FIG. 1 including the lower redistribution wiring layer 400 and the encapsulation structure ES stacked on the lower redistribution wiring layer 140 via the conductive bumps 302.

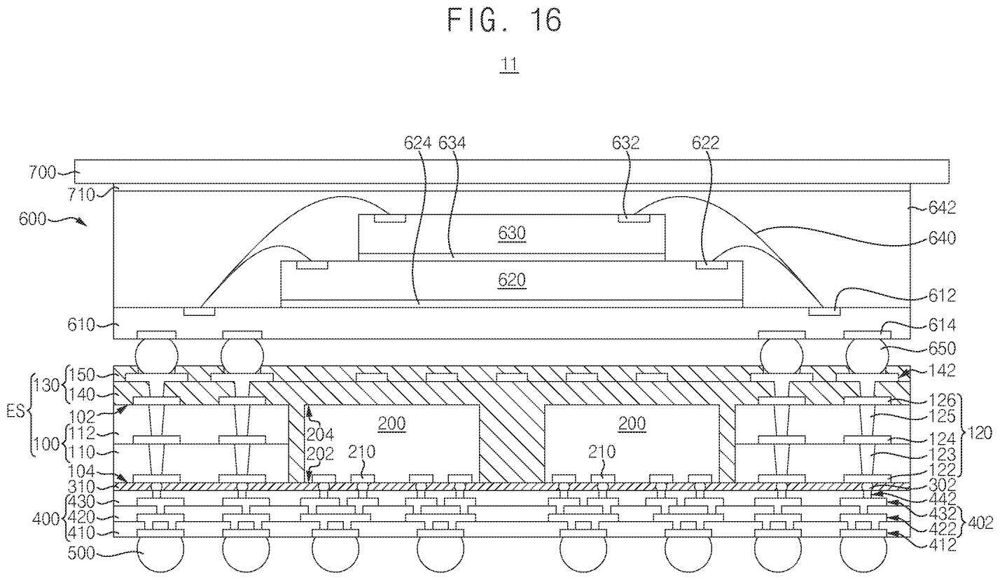

FIG. 16 is a cross-sectional view illustrating a semiconductor package in accordance with example embodiments. The semiconductor package may be substantially the same as the semiconductor package described with reference to FIG. 1 except for an additional second package. Thus, same reference numerals may be used to refer to the same or like elements and any further repetitive explanation concerning the above elements will be omitted.

Referring to FIG. 16, a semiconductor package 11 may include a first package and a second package 600 stacked on the first package. The first package may include a lower redistribution wiring layer 400, an encapsulation structure ES stacked on the lower redistribution wiring layer 400 via conductive bumps 302 and having a core substrate 100, a semiconductor chip 200 and an upper redistribution wiring layer 130, and an adhesive layer 310 interposed between the lower redistribution wiring layer 400 and the encapsulation structure ES. The first package may be substantially the same as or similar to the unit package described with reference to FIG. 1.

In example embodiments, the second package 600 may include a second package substrate 610, a plurality of second semiconductor chips 620 and 630 mounted on the second package substrate 610, and a sealing member 642 covering the second semiconductor chips 620 and 630 on the package substrate 610.

The second package 600 may be stacked on the first package via conductive connection members 650. For example, the conductive connection members 650 may be formed of or include solder balls, conductive bumps, etc. The conductive connection member 650 may be disposed between a bonding pad on the upper redistribution wiring layer 130 of the upper redistribution wiring layer 130 and a second connection pad 614 of the second package substrate 610. Accordingly, the first package and the second package 600 may be electrically connected to each other by the conductive connection members 650.

The plurality of second semiconductor chips 620 and 630 may be sequentially stacked on the second package substrate 610 by adhesive members 624 and 634. The bonding wirings 640 may connect the second chip pads 622 and 632 of the second semiconductor chips 620 and 630, respectively, to the first connection pads 612 of the second package substrate 610. The second semiconductor chips 620 and 630 may be electrically connected to the second package substrate 610 by bonding wirings 640.

Although the second package 600 includes two semiconductor chips mounted by a wiring bonding method, it will be understood that the number of the semiconductor chips in the second package and a mounting method are not limited thereto.

In example embodiments, the semiconductor package 11 may further include a heat sink 700 stacked on the second package 600. The heat sink 700 may be provided on the second package 600 to dissipate heat from the first and second packages to the outside. The heat sink 700 may be attached to the second package 600 by a thermal interface material (TIM) 710.

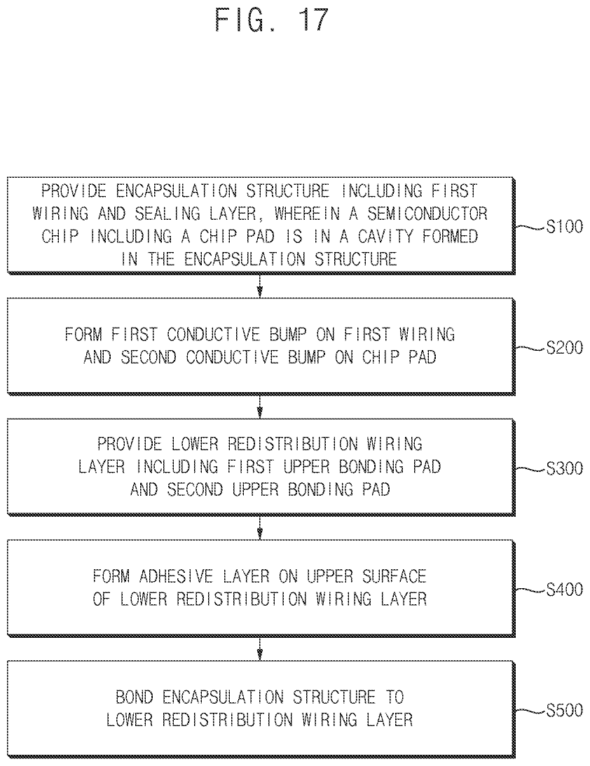

FIG. 17 shows a method of manufacturing a semiconductor package according to example embodiments.

An encapsulation structure may be provided (S100) including a first wiring and a sealing layer, wherein a semiconductor chip including a chip pad is in a cavity formed in the encapsulation structure and covered by the sealing layer.

A first conductive bump and a second conductive bump may be formed on the first wiring and the chip pad, respectively (S200).

A lower redistribution wiring layer may be provided (S300) including a first upper bonding pad and a second upper bonding pad exposed on an upper surface of the lower redistribution wiring layer.

An adhesive layer may be formed on the upper surface of the lower redistribution wiring layer (S400).

The encapsulation structure may be bonded to the lower redistribution wiring layer (S500).

The semiconductor package may include semiconductor devices such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments.

1. A semiconductor package comprising:
a lower redistribution wiring layer having lower redistribution wirings;
an encapsulation structure on the lower redistribution wiring layer;
a plurality of conductive bumps between the lower redistribution wiring layer and the encapsulation structure; and
an adhesive layer attaching the lower redistribution wiring layer to the encapsulation structure,
wherein the encapsulation structure includes:
a core substrate having a cavity formed therein;
at least one semiconductor chip in the cavity such that a front surface of the at least one semiconductor chip on which chip pads are formed faces the lower redistribution wiring layer; and
an upper redistribution wiring layer covering an upper surface of the core substrate and having upper redistribution wiring layers that are electrically connected to conductive structures of the core substrate.

2. The semiconductor package of claim 1, wherein the adhesive layer includes a non-conductive film.

3. The semiconductor package of claim 1, wherein each of the plurality of conductive bumps has a diameter within a range of 5 μm to 60 μm.

4. The semiconductor package of claim 1, wherein the lower redistribution wiring layer includes upper bonding pads on uppermost redistribution wirings of the lower redistribution wirings.

5. The semiconductor package of claim 4, wherein the plurality of conductive bumps include:
a first conductive bump between an upper bonding pad of the upper bonding pads and a chip pad of the chip pads of the at least one semiconductor chip; and
a second conductive bump between another upper bonding pad of the upper bonding pads and a conductive structure the conductive structures.

6. The semiconductor package of claim 4, wherein a diameter of an upper bonding pad of the upper bonding pads is equal to a diameter of a conductive bump of the conductive bumps.

7. The semiconductor package of claim 4, wherein an upper bonding pad of the upper bonding pads has a pillar shape.

8. The semiconductor package of claim 1, wherein the front surface of the at least one semiconductor chip is positioned on the same plane as a lower surface of the core substrate.

9. The semiconductor package of claim 1, wherein the upper redistribution wiring layer includes a sealing layer covering the upper surface of the core substrate and filling the cavity, and an upper insulating layer on the sealing layer and having the upper redistribution wiring layers, and
the sealing layer and the upper insulating layer include a same insulating material.

10. The semiconductor package of claim 1, further comprising:
a second package disposed on the upper redistribution wiring layer,
wherein the second package includes a package substrate and at least one second semiconductor chip stacked on the package substrate.

11. A semiconductor package, comprising:
a lower redistribution wiring layer having lower redistribution wirings;
a core substrate disposed on the lower redistribution wiring layer, the core substrate having a first surface and a second surface opposite to the first surface, the core substrate having a cavity formed therein;
at least one semiconductor chip in the cavity of the core substrate on the lower redistribution wiring layer such that a front surface of the at least one semiconductor chip on which chip pads are formed faces the lower redistribution wiring layer;
an upper redistribution wiring layer covering the first surface of the core substrate and having upper redistribution wirings that are electrically connected to conductive structures of the core substrate;
a plurality of conductive bumps disposed between the core substrate and the lower redistribution wiring layer and between the at least one semiconductor chip and the lower redistribution wiring layer; and
an adhesive layer disposed between the core substrate and the lower redistribution wiring layer and between the at least one semiconductor chip and the lower redistribution wiring layer, the adhesive layer covering side surfaces of the plurality of conductive bumps.

12. The semiconductor package of claim 11, wherein the lower redistribution wiring layer includes upper bonding pads disposed on uppermost lower redistribution wirings of the lower redistribution wirings.

13. The semiconductor package of claim 12, wherein the plurality of conductive bumps include:
a first conductive bump between an upper bonding pad of the upper bonding pads and a chip pad of the chip pads of the at least one semiconductor chip; and
a second conductive bump between another upper bonding pad of the upper bonding pads and a conductive structure of the conductive structures.

14. The semiconductor package of claim 12, wherein a diameter of an upper bonding pad of the upper bonding pads is equal to a diameter of a conductive bump of the plurality of conductive bumps.

15. The semiconductor package of claim 12, wherein an upper bonding pad of the upper bonding pads has a pillar shape.

16. The semiconductor package of claim 11, wherein the upper redistribution wiring layer includes:
a sealing layer covering the first surface of the core substrate and filling the cavity; and
an upper insulating layer on the sealing layer and having the upper redistribution wirings.

17. The semiconductor package of claim 16, wherein the sealing layer and the upper insulating layer of the upper redistribution wiring layer include a same insulating material.

18. The semiconductor package of claim 11, wherein each of the plurality of conductive bumps has a diameter within a range of 5 μm to 60 μm.

19. The semiconductor package of claim 11, wherein the adhesive layer includes a non-conductive film.

20. A semiconductor package, comprising:
a lower redistribution wiring layer having lower redistribution wirings;
an encapsulation structure on the lower redistribution wiring layer, the encapsulation structure including:
a core substrate,
at least one semiconductor chip, and
an upper redistribution wiring layer, wherein the core substrate has a first surface and a second surface opposite to the first surface and has a cavity formed therein, the at least one semiconductor chip is in the cavity and a front surface of the at least one semiconductor chip on which chip pads are formed is exposed from the second surface of the core substrate, and the upper redistribution wiring layer covers the first surface of the core substrate and a portion of the at least one semiconductor chip and has upper redistribution wirings that are electrically connected to conductive structures of the core substrate;
a plurality of conductive bumps between the lower redistribution wiring layer and the encapsulation structure and electrically connecting the chip pads to the lower redistribution wirings and electrically connecting the conductive structures to the lower redistribution wirings; and
an adhesive layer attaching the lower redistribution wiring layer to the encapsulation structure.

21-23. (canceled)
